(19) United States
(12) Patent Application Publication
(10) Pub. No.: US 2024/0260400 A1
(43) Pub. Date: Aug. 1, 2024

(54) DISPLAY DEVICE

(71) Applicant: LG Display Co., Ltd., Seoul (KR)

(72) Inventors: JongHwae LEE, Seongnam-si (KR); Juyeon WON, Gimpo-si (KR)

(73) Assignee: LG Display Co., Ltd., Seoul (KR)

(21) Appl. No.: 18/404,594

(22) Filed: Jan. 4, 2024

(30) Foreign Application Priority Data
Feb. 1, 2023 (KR) 10-2023-0013688

(51) Int. Cl. H10K 59/80

(52) U.S. Cl. CPC H10K 59/873

(57) ABSTRACT

A display device can include a substrate having an active area and a non-active area adjacent to the active area, an encapsulation substrate disposed over the substrate, a dam disposed in the non-active area between the substrate and the encapsulation substrate and an electrode disposed on a first surface of the encapsulation substrate or the substrate, and overlapping the dam. By forming the dam using the electrode, the dam can be more precisely disposed and the non-active area of the display device can be reduced.

### CROSS-REFERENCE TO RELATED APPLICATIONS

This application claims priority to Korean Patent Application No. 10-2023-0013688 filed on Feb. 1, 2023, in the Republic of Korea, the entire contents of which are hereby expressly incorporated by reference into the present application.

### BACKGROUND

### Technical Field

The present disclosure relates to a display device, and more particularly, to a display device having a reduction in size of a bezel area.

### Discussion of the Related Art

Recently, with advent of an information-oriented society that consumes information provided through displays, the field of display devices for visually expressing an electrical information signal to provide information has rapidly advanced. Various display devices having excellent performance in terms of thinness, lightness, and low power consumption, are being developed correspondingly to better provide information.

Representative display devices can include a liquid crystal display device (LCD), an electro-wetting display device (EWD), an organic light emitting display device (OLED), and the like.

Meanwhile, in the display device, a minimum bezel area, i.e., a non-active area, should be secured in order to secure reliability such as moisture permeation prevention to avoid damage to the display device. However, since the non-active area is an area that does not display an image, there is demand for increasing screen immersion and aesthetics by increasing a size of the active area that can display the image and reducing a size of the non-active area that does not display the image.

### SUMMARY OF THE DISCLOSURE

An object to be achieved by the present disclosure is to provide a display device having a reduction in a non-active area that is a bezel area.

Another object to be achieved by the present disclosure is to provide a display device in which a moisture permeation prevention performance is not degraded even when a non-active area is reduced.

Objects of the present disclosure are not limited to the above-mentioned objects, and other objects, which are not mentioned above, can be clearly understood by those skilled in the art from the following descriptions.

A display device according to an example embodiment of the present disclosure can include a substrate including an active area and a non-active area surrounding the active area, an encapsulation substrate disposed over the substrate, an adhesive film disposed between the substrate and the encapsulation substrate, a dam disposed in the non-active area between the substrate and the encapsulation substrate to surround the adhesive film and an electrode disposed on a lower surface of the encapsulation substrate overlapping the dam.

Other detailed matters of the example embodiments are included in the detailed description and the drawings.

According to the present disclosure, by forming a dam using an electrode, it is possible to precisely form the dam without a thickness variation.

According to the present disclosure, a process tolerance on one side of a display device can be eliminated by performing scribing on a dam. Therefore, according to the present disclosure, a bezel width can be reduced by reducing a non-active area through a removal of the process tolerance on the one side of the display device.

The effects according to the present disclosure are not limited to the contents exemplified above, and more various effects are included in the present specification.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a plan view of a mother board on which a plurality of display devices according to an example embodiment of the present disclosure are disposed.

FIG. 2 is a plan view of the display device according to an example embodiment of the present disclosure.

FIG. 3 is a cross-sectional view of a sub-pixel of the display device according to an example embodiment of the present disclosure.

FIG. 4 is a cross-sectional view of the display device taken along IV-IV′ of FIG. 2.

FIG. 5 is a view for explaining a method of forming a dam in the display device according to an example embodiment of the present disclosure.

FIG. 6 is a plan view of a display device according to another example embodiment of the present disclosure.

FIG. 7 is a cross-sectional view of the display device taken along VII-VII′ of FIG. 6.

FIGS. 8A-8D are cross-sectional views of the display device taken along IV-IV′ of FIG. 2 according to other example embodiments of the present disclosure.

FIGS. 9A and 9B are cross-sectional views of the display device taken along IV-IV′ of FIG. 2 according to other example embodiments of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components. Therefore, a first component to be mentioned below can be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, example embodiments of the present disclosure will be described in detail with reference to accompanying drawings.

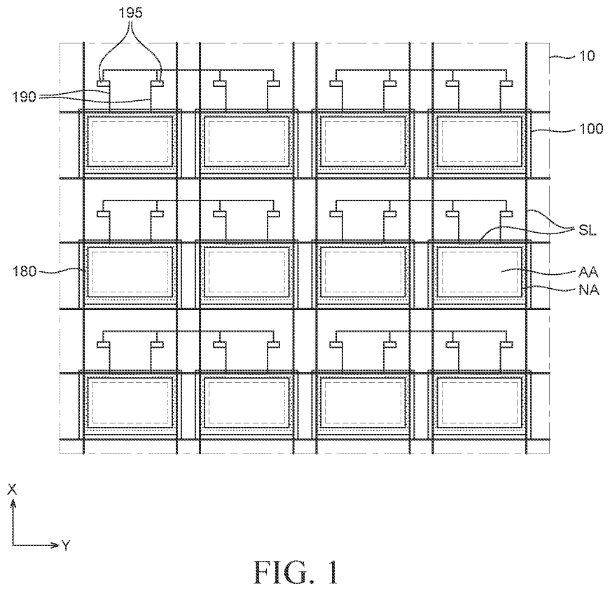

FIG. 1 is a plan view of a mother board on which a plurality of display devices according to an example embodiment of the present disclosure are disposed.

Referring to FIG. 1, a plurality of display devices 100 according to an example embodiment of the present disclosure can be arranged in units of cells on a mother board 10. The display devices 100 can be arranged in a matrix form on the mother board 10. Here, the mother board 10 can include a mother lower substrate for supporting components of the display device 100 and a mother encapsulation substrate disposed to face the mother lower substrate. The mother board 10 can also be referred to as a parent board. All components of each display device according to all embodiments of the present disclosure are operatively coupled and configured.

The mother board 10 can include a glass material. Since the mother board 10 formed of a glass material is more rigid compared to a substrate of the display device 100 formed of a plastic material, the display device 100 can be formed without a support substrate. Thus, a process of attaching and detaching the support substrate can be simplified. But embodiments of the present disclosure are not limited thereto. Other rigid materials, such quarts can also be used for the mother board.

Scribing lines SL can be disposed on the mother board 10. The scribing lines SL can be arranged to surround or define each cell corresponding to a display device 100. The scribing lines SL can separate the display devices 100 constituting a plurality of cells on the mother board 10 into individual units using a laser beam or a wheel cutter. But embodiments of the present disclosure are not limited thereto, and other cutting means such as a pressurized jet of liquid, such as water, can also be used.

A portion of the scribing lines SL can be disposed to overlap dams 180 formed in the non-active areas NA of each of the display devices 100. More specifically, the scribing lines SL can be disposed in a first direction X and a second direction Y, and one of the scribing lines SL disposed in the second direction Y can be disposed not to overlap the dam 180 and the other of the scribing lines SL can be disposed to overlap the dam 180. The scribing line SL that does not overlap the dam 180 can be a scribing line SL disposed on one end (or one side) of the display device 100 connected to flexible films that are electrically connected to the display device 100. For example, the scribing lines SL can be disposed to overlap the dam 180 on three sides among four sides of the display device 100. For example, the scribing lines SL can be disposed to overlap the dam 180 surrounding an upper side, a right side, and a left side of each cell in FIG. 1, and can be disposed to be spaced apart from the dam 180 disposed on a lower side of the cell. Accordingly, in the display device 100, a lower side of the non-active area NA can have a width greater than a width of the upper, left, and right sides of the non-active area NA. However, the present disclosure is not limited thereto, and the scribing lines SL can be adjusted so that the non-active area NA can have various widths at the upper, lower, left and right sides of the non-active area NA.

Therefore, the display devices 100 according to an example embodiment of the present disclosure are separated into each of the display devices 100 along the scribing lines SL that are formed to overlap the dams 180 on the mother board 10, so that a size of a bezel area BA can be reduced.

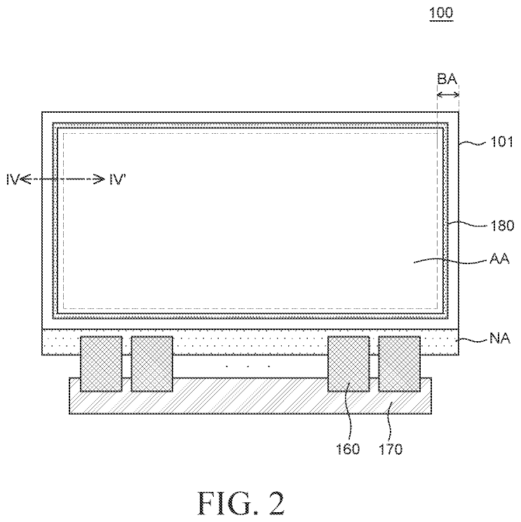

FIG. 2 is a plan view of the display device according to an example embodiment of the present disclosure.

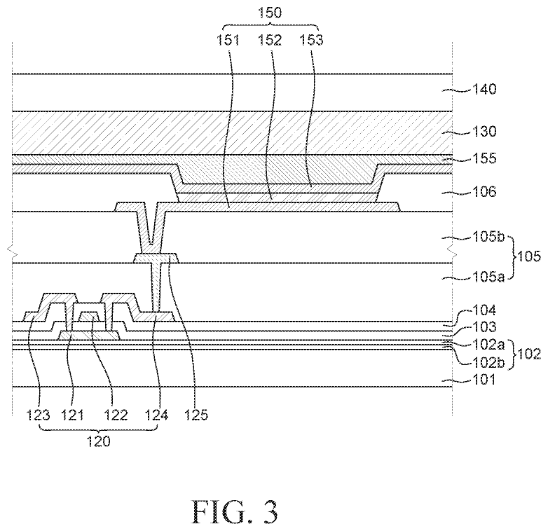

FIG. 3 is a cross-sectional view of a sub-pixel of the display device according to an example embodiment of the present disclosure.

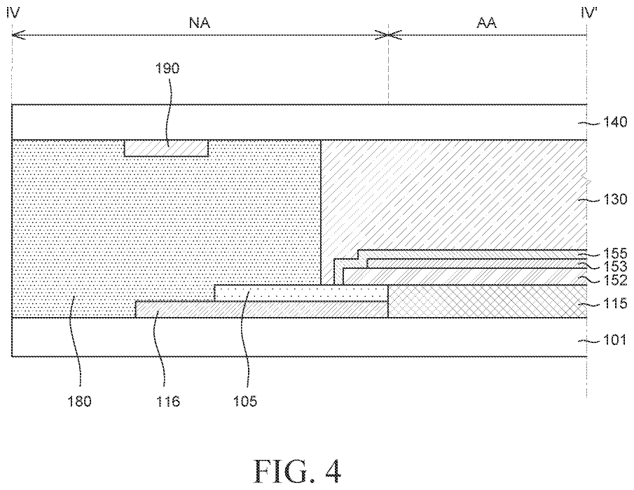

FIG. 4 is a cross-sectional view of the display device taken along IV-IV′ of FIG. 2.

For convenience of explanation, in FIG. 2, among various components of the display device 100, a substrate 101, a plurality of flexible films 160, a printed circuit board 170, and the dam 180 are illustrated as an example.

FIG. 4 schematically illustrates a pixel unit 115 in an active area AA and a gate-in-panel (GIP) unit 116 in a non-active area NA for convenience of description. The pixel unit 115 and the GIP unit 116 can include various components under an organic layer 152. The pixel unit 115 can include various components under the organic layer 152, for example, a driving element 120. In addition, the GIP unit 116 in the non-active area NA can also include various components, and is schematically illustrated for convenience of explanation.

Referring to FIG. 2, the substrate 101 is a support member for supporting other components of the display device 100.

A plurality of pixels for displaying an image, driving elements for driving the plurality of pixels, and lines for transmitting various signals to the plurality of pixels and driving elements can be disposed on the substrate 101.

The substrate 101 can include an active area AA and a non-active area NA.

The active area AA is an area where the plurality of pixels are disposed to substantially display an image. A plurality of sub-pixels constituting the plurality of pixels and circuits for driving the plurality of sub-pixels can be disposed in the active area AA. The plurality of sub-pixels are minimum units constituting the active area AA, and a light emitting element can be disposed in each of the plurality of sub-pixels. For example, an organic light emitting element including an anode, an organic light emitting layer, and a cathode can be disposed in each of the plurality of sub-pixels, but the present disclosure is not limited thereto as other types of light emitting elements, such as micro-LEDs can also be used. In addition, the circuits for driving the plurality of sub-pixels can include driving elements, lines and the like. For example, the circuits can include thin film transistors, a storage capacitor, gate lines, data lines, and the like, but the embodiment of the present disclosure is not limited thereto.

A configuration of the sub-pixel disposed in the active area AA will be described in more detail.

Referring to FIG. 3, the sub-pixel disposed in the active area AA can include the substrate 101, a buffer layer 102, an insulating layer 103, a gate insulating layer 104, the driving element 120, a planarization layer 105, a bank 106, a light emitting element 150, a passivation layer 155, an adhesive film 130, and an encapsulation substrate 140. But embodiments of the present disclosure are not limited thereto.

For example, the substrate 101 is a support substrate on which the plurality of pixels are disposed and can be formed of transparent glass. When manufacturing a flexible display device, the substrate 101 can be formed of a flexible organic material such as a plastic-based material. For example, the substrate 101 can be formed of a material such as polyimide. But embodiments of the present disclosure are not limited thereto.

A plurality of inorganic insulating layers can be disposed on the substrate 101. The inorganic insulating layers can extend to the non-active area NA. The inorganic insulating layers can include the buffer layer 102, the insulating layer 103, and the gate insulating layer 104.

For example, the buffer layer 102 can be a functional layer for protecting various electrodes and lines from impurities such as alkali ions flowing out from the substrate 101 or lower layers thereof, and can have a multilayer structure formed of a first buffer layer 102a and a second buffer layer 102b. However, the present disclosure is not limited thereto. The buffer layer 102 can be formed of silicon oxide (SiOx), silicon nitride (SiNx), or a multilayer thereof.

The buffer layer 102 can retard diffusion of moisture and/or oxygen penetrating into or from the substrate 101. In addition, the buffer layer 102 can include a multi-buffer and/or an active buffer. The active buffer can protect an active layer 121 formed of a semiconductor among components of the driving element 120 and can perform a function of blocking various types of defects introduced from the substrate 101. The active buffer can be formed of amorphous silicon (a-Si) or the like. Accordingly, the buffer layer 102 can be a combination of organic and inorganic layers, for example.

The driving element 120 can be in a form in which the active layer 121, the insulating layer 103, a gate electrode 122, the gate insulating layer 104, a source electrode 123, and a drain electrode 124 are sequentially disposed. The driving element 120 can be electrically connected to the light emitting element 150 through a connection electrode 125 to transmit a current or signal to the light emitting element 150.

The active layer 121 can be located on the buffer layer 102. The active layer 121 can be formed of polysilicon (p-Si), and in this case, a predetermined region thereof can be doped with impurities. Further, the active layer 121 can be formed of amorphous silicon (a-Si) or can be formed of various organic semiconductor materials such as pentacene and the like. Furthermore, the active layer 121 can be formed of an oxide semiconductor.

The insulating layer 103 can be located on the active layer 121. The insulating layer 103 can be formed of an insulating inorganic material such as silicon oxide (SiOx) or silicon nitride (SiNx), and can also be formed of an insulating organic material or the like. But embodiments of the present disclosure are not limited thereto.

The gate electrode 122 can be located on the insulating layer 103. The gate electrode 122 can be formed of various conductive materials, for example, magnesium (Mg), aluminum (Al), nickel (Ni), chromium (Cr), molybdenum (Mo), tungsten (W), gold (Au), or an alloy thereof. But embodiments of the present disclosure are not limited thereto.

The gate insulating layer 104 can be located on the gate electrode 122. The gate insulating layer 104 can be formed of an insulating material such as silicon oxide (SiOx) or silicon nitride (SiNx), and can also be formed of an insulating organic material or the like. But embodiments of the present disclosure are not limited thereto.

In addition, contact holes for electrically connecting the source electrode 123 and the drain electrode 124 with the active layer 121 can be formed in the insulating layer 103 and the gate insulating layer 104. The source electrode 123 and the drain electrode 124 can be formed on the gate insulating layer 104 in a single-layer or multilayer structure of an electrode material. If necessary, an additional passivation layer formed of an inorganic insulating material can be formed to cover the source electrode 123 and the drain electrode 124.

In FIG. 3, a color filter can be further disposed on the gate insulating layer 104. The color filter can be disposed to correspond to an emission area where the light emitting element 150 is disposed. In this manner, when the color filter is disposed on the gate insulating layer 104 to correspond to the emission area, light emission of the display device in a bottom emission method can be more effectively performed.

The planarization layer 105 can be disposed on the driving element 120 configured as described above.

The planarization layer 105 can be formed of a single layer, or as shown in FIG. 3, for example, the planarization layer 105 can have a multilayer structure composed of at least two layers including a first planarization layer 105a and a second planarization layer 105b. The first planarization layer 105a can be disposed to cover the driving element 120 in such a manner that portions of the source electrode 123 and the drain electrode 124 of the driving element 120 are exposed.

For example, the connection electrode 125 for electrically connecting the driving element 120 and the light emitting element 150 can be disposed on the first planarization layer 105a. In addition, in FIG. 3, various metal layers serving as electric lines/electrodes such as data lines and signal lines can be disposed on the first planarization layer 105a.

In addition, the second planarization layer 105b can be disposed on the first planarization layer 105a and the connection electrode 125.

In the display device 100 according to an example embodiment of the present disclosure, the planarization layer 105 is formed of two layers due to an increase of various signal lines as the display device 100 has a higher resolution. Accordingly, an additional layer is formed since it is difficult to place all the lines on one layer while securing a minimum distance therebetween. Due to the addition of such an additional layer, for example, the second planarization layer 105b, a margin is generated in arrangement of the lines, and line/electrode arrangement design can be further facilitated. In addition, when a dielectric material is used for the planarization layer 105 formed of multiple layers, the planarization layer 105 can also be used for forming capacitance between metal layers. The planarization layer 105 can extend to the non-active area NA.

The second planarization layer 105b can be formed to expose a portion of the connection electrode 125, and the drain electrode 124 of the driving element 120 and an anode 151 of the light emitting element 150 can be electrically connected by the connection electrode 125.

The light emitting element 150 can be configured by sequentially disposing the anode 151, the organic layer 152, and a cathode 153. For example, the light emitting element 150 can include the anode 151 formed on the planarization layer 105, the organic layer 152 formed on the anode 151, and the cathode 153 formed on the organic layer 152. The organic layer 152 can be formed by stacking a plurality of organic layers.

The display device 100 can be implemented in a top emission method or type or a bottom emission method or type. In the case of the top emission method, a reflective layer formed of an opaque conductive material having high reflectivity, such as silver (Ag), aluminum (Al), gold (Au), molybdenum (Mo), tungsten (W), chromium (Cr), or an alloy thereof, can be added under the anode 151 such that light emitted from the organic layer 152 is reflected by the anode 151 and directed upward, for example, in a direction of the cathode 153 located thereabove. On the other hand, in the case of the bottom emission method, the anode 151 can be formed of a transparent conductive material such as indium tin oxide (ITO), indium zinc oxide (IZO), or indium gallium zinc oxide (IGZO). Hereinafter, descriptions will be made on the assumption that the display device 100 of the present disclosure is in the top emission method. However, the present disclosure is not limited thereto.

The bank 106 can be disposed on the planarization layer 105 in an area other than the emission area. The bank 106 can have a bank hole exposing the anode 151 so as to correspond to the emission area. The bank 106 can be formed of an inorganic insulating material such as silicon nitride (SiNx) or silicon oxide (SiOx) or an organic insulating material such as BCB, acrylic resin, or imide resin. But embodiments of the present disclosure are not limited thereto.

The organic layer 152 can be disposed on the anode 151 exposed by the bank 106. The organic layer 152 can include a light emitting layer, an electron injection layer, an electron transport layer, a hole transport layer, a hole injection layer, and the like. But embodiments of the present disclosure are not limited thereto. The organic layer 152 can extend to the non-active area NA.

The cathode 153 can be disposed on the organic layer 152. In the case of the top emission method, the cathode 153 can include a transparent conductive material. For example, the cathode 153 can be formed of indium tin oxide (ITO), indium zinc oxide (IZO), or indium gallium zinc oxide (IGZO). But embodiments of the present disclosure are not limited thereto. In the case of the bottom emission method, the cathode 153 can include any one of the group consisting of metal materials such as gold (Au), silver (Ag), aluminum (Al), molybdenum (Mo), magnesium (Mg), palladium (Pd), and copper (Cu), or alloys of them. But embodiments of the present disclosure are not limited thereto. Alternatively, the cathode 153 can be configured by stacking a layer formed of a transparent conductive material such as indium tin oxide (ITO), indium zinc oxide (IZO), or indium gallium zinc oxide (IGZO), and a layer formed of a metal material such as gold (Au), silver (Ag), aluminum (Al), molybdenum (Mo), magnesium (Mg), palladium (Pd), or copper (Cu), or an alloy thereof, but the present disclosure is not limited thereto. The cathode 153 can extend to the non-active area NA.

The passivation layer 155 can be disposed on the light emitting element 150. The passivation layer 155 can protect the light emitting element 150 from external foreign materials, impacts, penetration of moisture and oxygen, and the like. The passivation layer 155 can be formed of an inorganic material, and for example, the passivation layer 155 can be formed of an inorganic material such as silicon oxide (SiOx) or silicon nitride (SiNx). The passivation layer 155 can extend to the non-active area NA and can be omitted if necessary.

The adhesive film 130 and the encapsulation substrate 140 can be disposed on the passivation layer 155.

The adhesive film 130 can be disposed to surround, cover or envelop the passivation layer 155.

The adhesive film 130 together with the passivation layer 155 and the encapsulation substrate 140 can protect the pixel unit 115 and the light emitting element 150 from external moisture, oxygen, impacts, and the like. The adhesive film 130 can further include a moisture absorbent. The moisture absorbent can be particles having hygroscopicity, and can absorb moisture and oxygen from the outside to minimize penetration of moisture and oxygen into the light emitting element 150. However, the present disclosure is not limited thereto.

For example, the adhesive film 130 can include a filler. The filler can be formed of a transparent material so that luminance is not lowered in a process in which light emitted from the light emitting element 150 is transmitted through the encapsulation substrate 140. The filler can be composed of epoxy or olefin, and can include talc, calcium oxide (CaO), barium oxide (BaO), zeolite, silicon oxide (SiO), and the like.

For example, the encapsulation substrate 140 can be disposed on the adhesive film 130. The encapsulation substrate 140, together with the adhesive film 130, can protect the pixel unit 115 including the driving element 120 and the light emitting element 150. The encapsulation substrate 140 can protect the light emitting element 150 from external moisture, oxygen, impacts, and the like. The encapsulation substrate 140 can be disposed on an upper portion of the substrate 101 such that a pad unit that is electrically connected to the plurality of flexible films 160 disposed on one side of the substrate 101 is exposed. For example, the adhesive film 130 and the encapsulation substrate 140 can extend to the non-active area NA.

Referring to FIG. 2, the non-active area NA is an area in which an image is not displayed.

In FIG. 2, it is illustrated that the non-active area NA surrounds the active area AA having a rectangular shape, but shapes and arrangements of the active area AA and the non-active area NA are not limited to an example shown in FIG. 2. For example, the active area AA and the non-active area NA can have shapes suitable for a design of an electronic device in which the display device 100 is mounted. For example, an example shape of the active area AA can be a pentagonal shape, a hexagonal shape, a circular shape, or an elliptical shape. But embodiments of the present disclosure are not limited thereto.

Various lines and circuits for driving the light emitting elements 150 in the active area AA can be disposed in the non-active area NA. For example, in the non-active area NA, link lines or driver ICs such as gate driver ICs and data driver ICs can be disposed to transfer signals to the plurality of sub-pixels and circuits of the active area AA, but the present disclosure is not limited thereto.

The display device 100 can include various additional elements for generating various signals or driving the plurality of pixels arranged in the active area AA. The additional elements for driving the pixels can include an inverter circuit, a multiplexer, an electrostatic discharge (ESD) circuit, and the like. The display device 100 can also include additional elements related to functions other than pixel driving. For example, the display device 100 can include additional elements that provide a touch sensing function, a user authentication function (e.g., fingerprint recognition), a multi-level pressure sensing function, a tactile feedback function, and the like. The aforementioned additional elements can be located in the non-active area NA and/or in an external circuit connected to a connection interface. But embodiments of the present disclosure are not limited thereto.

The plurality of flexible films 160 are films in which various parts are disposed on flexible base films. Specifically, the flexible film 160 can be a film for supplying signals to the plurality of sub-pixels and circuits of the active area AA, and can be electrically connected to the substrate 101. The flexible film 160 can be disposed on one end of the non-active area NA in the substrate 101 and supply power voltages, data voltages, and the like to the plurality of sub-pixels and circuits of the active area AA. The number of flexible films 160 can be variously changed according to design.

Meanwhile, the driver ICs such as a gate driver IC and a data driver IC can be disposed on the flexible film 160. The driver IC is a component that processes data for displaying an image and a driving signal for processing the data. The driver IC can be disposed in a method such as a chip on glass (COG) method, a chip on film (COF) method, or a tape carrier package (TCP) method depending on a mounting method.

The printed circuit board 170 can be disposed on one end of the flexible films 160 and connected to the flexible films 160. For example, the printed circuit board 170 is a component that supplies signals to the driver ICs. The printed circuit board 170 can supply various signals such as driving signals and data signals to the driver ICs. For example, a data driver for generating data signals can be mounted on the printed circuit board 170, and the generated data signals can be supplied to the plurality of sub-pixels and circuits of the substrate 101 through the flexible films 160. The number of printed circuit boards 170 can be variously changed according to design, but the present disclosure is not limited thereto.

Referring to FIGS. 1, 2, and 4 together, the dam 180 can be disposed in the non-active area NA outside the active area AA. For example, the dam 180 is formed to surround the pixel unit 115 including the light emitting element 150 and the adhesive film 130 in a cross-section, and can bond and seal the substrate 101 and the encapsulation substrate 140 together with the adhesive film 130. Accordingly, the dam 180 can be disposed in an area where the substrate 101 and the encapsulation substrate 140 overlap each other at a periphery of the substrate 101 and the encapsulation substrate 140. As described above, in the display device 100 according to an example embodiment of the present disclosure, the dam 180 is disposed between the substrate 101 and the encapsulation substrate 140 at an edge or the periphery of the substrate 101 so that adhesion between the substrate 101 and the encapsulation substrate 140 can be reinforced and moisture can be blocked.

A side surface of the dam 180 can be disposed on the same plane as side surfaces of the substrate 101 and the encapsulation substrate 140. For example, each of the side surfaces of the substrate 101, the encapsulation substrate 140, and the dam 180 can be disposed on the same plane or be coplanar by the same process, for example, a scribing process. As described above, since the scribing lines SL for separating the mother board 10 into units of the display devices 100 are disposed to overlap the dams 180, the mother board 10 disposed outside the display devices 100 and portions of components (for example, pads for applying an electric field to a nozzle for forming the dam 180 to be described later) disposed on the mother board 10 can be removed by the scribing process. Accordingly, the side surface of the dam 180 can be disposed on the same plane as the side surfaces of the substrate 101 and the encapsulation substrate 140. Thus, in the display device 100 according to an example embodiment of the present disclosure, the size of the bezel area BA can be reduced.

Referring to FIG. 4, an electrode 190 can be disposed on the encapsulation substrate 140 between the substrate 101 and the dam 180. Specifically, the electrode 190 can be disposed on a lower surface of the encapsulation substrate 140 to face an upper surface of the substrate 101. The electrode 190 can be disposed to overlap the dam 180. The location of the electrode 190 relative to the dam 180 can vary. For example, the electrode 190 can be located about midway in a width direction of the dam 180, but embodiments of the present disclosure are not limited thereto. For example, in other embodiments of the present disclosure, the electrode 190 can be located closer to the edge of the encapsulation substrate 140, or can be located closer to the adhesive film 130. Additionally, the electrode 190 can overlap at least one of the GIP unit 116 and the planarization layer 105, but embodiments of the present disclosure are not limited thereto. For example, the electrode 190 can be located so as not to overlap the GIP unit 116 or the planarization layer 105 in other embodiment of the present disclosure. In various embodiments of the present disclosure, the electrode 190 can be located at the entire periphery of the active area AA in each display device 100, and can form a loop. In embodiments of the present disclosure, the scribing lines SL can be defined by the electrode 190. For example, the scribing line SL can overlap or be aligned with the electrode 190, such as when the electrode 190 forms a loop.

Meanwhile, the GIP unit 116 can be disposed in the non-active area NA of the substrate 101.

In the GIP unit 116, for example, various elements constituting a GIP of a gate driving circuit (such as transistors and capacitors) can be disposed.

The planarization layer 105 can be disposed on the GIP unit 116 configured as described above.

The planarization layer 105 can extend to the non-active area NA to cover a portion of the GIP unit 116, but is not limited thereto.

For example, the dam 180 can partially overlap the GIP unit 116. In addition, the dam 180 can partially overlap the planarization layer 105.

Further, for example, the electrode 190 can partially or entirely overlap the GIP unit 116. Also, the dam 180 need not overlap the passivation layer 155, but embodiments of the present disclosure are not limited thereto. When there is no overlap of the dam 180 with the passivation layer 155, the adhesive film 130 can contact the planarization layer 105.

In addition, the display device 100 according to an example embodiment of the present disclosure can allow for a reduction of the non-active area NA by performing scribing on the dam 180. For example, when a scribing process is performed on dam 180 in a state where the dam 180 is formed to have a width greater than a required width of the dam 180 which is necessary to prevent or reduce moisture permeation and improve adhesive properties, a portion of the side surface of the dam 180 can be removed during the scribing process, and the side surface of the encapsulation substrate 140, the side surface of the dam 180, and the side surface of the substrate 101 can be disposed on the same plane. Therefore, in the display device 100 according to an example embodiment of the present disclosure, since the encapsulation substrate and the substrate that are disposed on one side of the dam 180 are removed, the non-active area extending to the one side of the dam 180 is reduced, so that an overall width and area of the non-active area NA can be reduced. Therefore, a bezel width is significantly reduced compared to a conventional case.

The dam 180 can be formed on the mother board 10 in a state before being separated into units of the display devices 100.

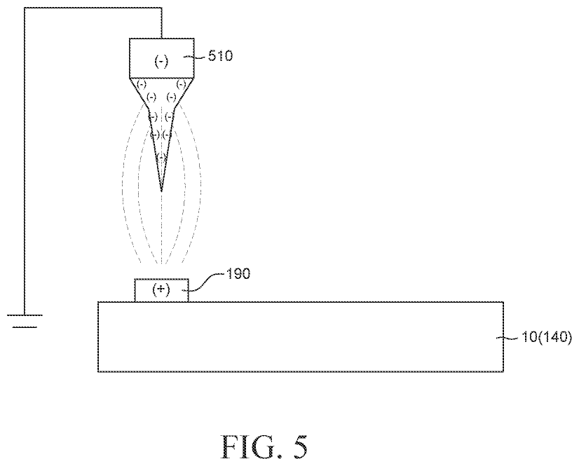

FIG. 5 is a view for explaining a method of forming a dam in the display device according to an example embodiment of the present disclosure.

More specifically, referring to FIGS. 1 and 5 together, when the electrode 190 to which a positive (+) voltage is applied through pads 195 formed on the mother board 10 is disposed on the encapsulation substrate 140 of the display device 100, and a ground connection is made such that a minus (−) voltage is applied to an electric field application nozzle 510 for forming an electric field with respect to a dam forming material which is discharged on the electrode 190, the dam forming material inside the electric field application nozzle 510 can be discharged onto the electrode 190 to form the dam 180. In this case, the dam 180 is a dam forming material before the scribing process and can have a width greater than a width of the dam 180 after the scribing process. Subsequently, when the scribing process is performed along the scribing lines SL formed by overlapping the mother board 10 with the dams 180, the pads 195 for applying the positive (+) voltage to the electrode 190 are removed, and only the electrode 190 to which the positive (+) voltage is applied, for example, only a line remains. Then, the dam forming material before the scribing process can be partially removed so that the dam 180 that is consistent with the side surfaces of the substrate 101 and the encapsulation substrate 140 can be formed. In forming the dam 180 using the electric field application nozzle 510, the dam forming material can be placed over the electrode 190 in various ways. For example, the dam forming material can be placed over the electrode 190 in sequential layers to increase a height of the dam 180 as additional dam forming material are discharged on the electrode 190, or the dam forming material can be deposited in sufficient amount to form the height of the dam 180 as the electric field application nozzle 510 is drawn away from the electrode 190, either gradually or in incremental steps.

Accordingly, in the display device 100 according to an example embodiment of the present disclosure, a width of the dam 180 disposed on the upper, right, and left sides of the display device 100 overlapping the scribing lines SL, and a width of the dam 180 disposed on the lower side of the display device 100 that does not overlap with the scribing lines SL can be different from each other. More specifically, the width of the dam 180 disposed on the upper, right, and left sides of the display device 100 can be smaller than the width of the dam 180 disposed on the lower side of the display device 100.

In addition, the side surface of the electrode 190 from which the pad 195 is removed by the scribing process can be exposed. For example, one end of the electrode 190 can be exposed on one side of the substrate 101. In other embodiments of the present disclosure, when the scribing process is performed, the electrode 190 can be cut, either partially so that a portion of the electrode 190 remains on the encapsulation substrate 140, or the portion of the encapsulation substrate 140 with the electrode 190 can be entirely cut to eliminate the electrode 190.

In general, characteristics of an organic layer of a light emitting element can be rapidly degraded when it is exposed to moisture or oxygen. Therefore, it is important to prevent degradation of the organic light emitting element from permeation of moisture and oxygen by using encapsulation techniques for sealing the light emitting element from external environments.

In the case of using a dam among various sealing techniques, the dam serves to block moisture penetrating from a side surface of a device or serves to retard penetration of moisture. At this time, a moisture permeation prevention performance of the dam can be determined by a material constituting the dam and a width of the dam. However, an increase in moisture permeation prevention performance of the material constituting the dam is determined in a material aspect, which is difficult to be improved in a manufacturing process of the display device. Therefore, it is important to increase a width of the dam in order to increase the moisture permeation prevention performance of the dam in the manufacturing process of the display device. There is a limit to reducing the width of the dam to reduce a size of the non-active area. In addition, the dam is generally manufactured by an application method through a dispenser process, but since the dispenser process is a method of controlling the amount of application with pneumatics, it is difficult to precisely control a process margin.

Accordingly, the display device 100 according to an example embodiment of the present disclosure provides that the dam 180 and the scribing lines SL are arranged to overlap each other and the scribing process is performed on the dam 180, so that the non-active area NA, in particular, the bezel area BA can be reduced. Specifically, in a state in which the dam forming material is applied wider than a required width of the dam 180 which is necessary to prevent moisture permeation, the dam 180 and the scribing lines SL are located to overlap each other. Then, when the scribing process is performed along the scribing lines SL overlapping the dam 180, a part of the dam 180 is removed during the scribing process, and the side surface of the encapsulation substrate 140, the side surface of the dam 180 and the side surface of the substrate 101 are disposed on the same plane. Therefore, in the display device 100 according to an example embodiment of the present disclosure, since a portion of the dam, the encapsulating substrate, and the substrate that are disposed on one side of the dam 180 are removed, the non-active area extending to the one side of the dam 180 can be removed, and an overall area of the non-active area NA can be reduced.

In addition, the display device 100 according to an example embodiment of the present disclosure can provide a display device 100 in which a moisture permeation prevention performance is not degraded even when the non-active area NA is reduced. As described above, the scribing process can be conducted in a manner in which a required width of the dam 180 necessary for preventing moisture permeation is left in a state in which a dam material is applied wider than the required width of the dam 180 required for preventing moisture permeation. Therefore, in the display device 100 according to an example embodiment of the present disclosure, although the non-active area NA is reduced, the width of the dam 180 for maintaining a moisture permeation prevention performance is maintained, so that reliability such as moisture permeation prevention can be secured.

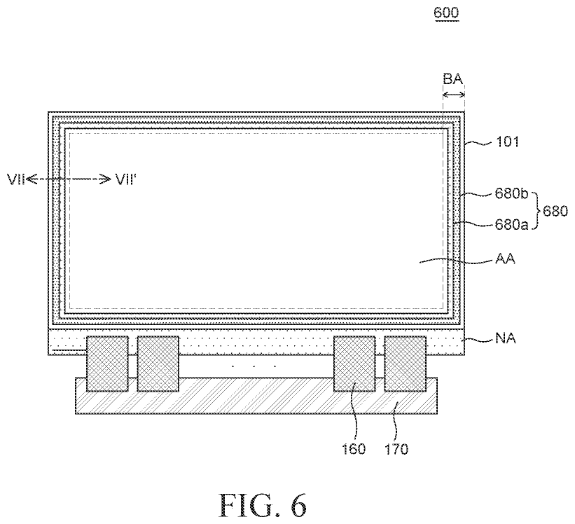

FIG. 6 is a plan view of a display device according to another example embodiment of the present disclosure.

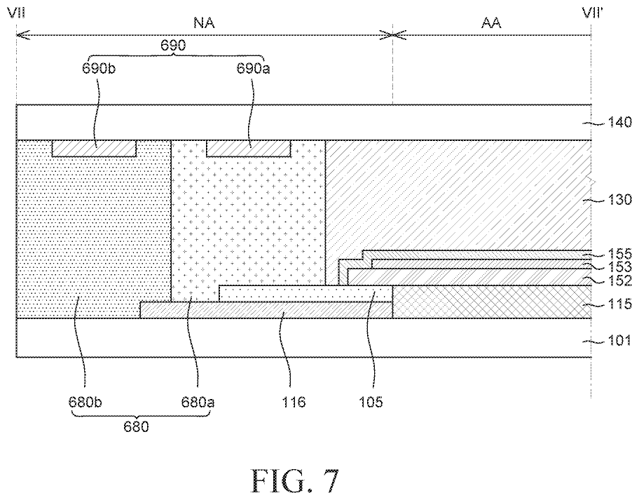

FIG. 7 is a cross-sectional view of the display device taken along VII-VII′ of FIG. 6.

Since other configurations of a display device 600 according to another example embodiment of the present disclosure are substantially identical to those of the display device 100 according to an example embodiment of the present disclosure in FIGS. 2 to 4 with only differences in configurations of dams 680 and electrodes 690, redundant descriptions will be omitted. The same reference numerals will be used for the same components. Hereinafter, a description of the same reference numerals can be made with reference to FIGS. 2 to 4.

The dams 680 can include a first dam 680a and a second dam 680b.

The first dam 680a can be disposed between the active area AA and the second dam 680b. For example, the first dam 680a can be disposed to surround the active area AA. The first dam 680a can be formed of a material including a material having higher adhesion than that of the second dam 680b.

For example, the second dam 680b can be disposed to surround the first dam 680a. Since the second dam 680b is disposed on an outermost side of the display device 600, it can be formed of a material that has moisture permeation prevention properties higher than those of the first dam 680a.

In addition, the second dam 680b can be located on the same plane as the side surfaces of the substrate 101 and the encapsulation substrate 140 at an upper edge, a left edge, and a right edge of the display device 600. This is because scribing lines SL are disposed on the second dam 680b that is disposed along the upper, left, and right edges of the display device 600 constituting a unit cell on the mother board 10.

The electrodes 690 can be disposed on the lower surface of the encapsulation substrate 140. The electrodes 690 can include a first electrode 690a and a second electrode 690b.

For example, the first electrode 690a is an electrode for forming the first dam 680a and can be disposed to overlap the first dam 680a.

Further, the second electrode 690b is an electrode for forming the second dam 680b and can be disposed to overlap the second dam 690b.

In addition, the first electrode 690a and the second electrode 690b can be alternately driven when forming the first dam 680a and the second dam 680b.

More specifically, when forming the first dam 680a, as described above, a negative (−) voltage is applied to the electric field application nozzle 510. Thus, by applying a positive voltage (+) to the first electrode 690a and applying a negative (−) voltage to the second electrode 690b, a dam forming material can be discharged on the first electrode 690a to thereby form the first dam 680a.

On the other hand, when forming the second dam 680b, a negative (−) voltage is applied to the electric field application nozzle 510. Thus, by applying a negative (−) voltage to the first electrode 690a and applying a positive voltage (+) to the second electrode 690b, a dam forming material can be discharged on the second electrode 690b to thereby form the second dam 680b.

As described above, in the display device 600 according to another example embodiment of the present disclosure, the dams 680 are formed by including the first electrode 690a for forming the first dam 680a and the second electrode 690b for forming the second dam 680b, so that the dams 680 can be more precisely formed, and the size of the bezel area BA can be reduced.

Meanwhile, according to another example embodiment of the present disclosure, for example, the first dam 680a and the second dam 680b can be simultaneously formed. In this case, a negative (−) voltage is applied to the electric field application nozzle 510 for forming the first dam 680a. Thus, the first dam 680a can be formed by applying a positive voltage (+) to the first electrode 690a so that a dam forming material is discharged on the first electrode 690a. In addition, a positive (+) voltage is applied to another electric field application nozzle for forming the second dam 680b. Thus, the second dam 680b can be simultaneously formed by applying a minus (−) voltage to the second electrode 690b so that a dam forming material is discharged on the second electrode 690b.

In addition, in the display device 600 according to another example embodiment of the present disclosure, the first dam 680a that is disposed to surround the active area AA is formed to include a dam forming material having adhesion higher than that of a dam forming material constituting the second dam 680b. In addition, the second dam 680b is formed to include a material having moisture permeation prevention properties higher than those of the dam forming material constituting the first dam 680a. Thus, degradation of the light emitting element 150 is prevented, and reliability of the display device 600 can be improved.

Further, as described above, side surfaces of the first electrode 690a and the second dam 680b from which pads are removed by the scribing process can be exposed. For example, on one side of the substrate 101, one ends of the first electrode 690a and the second electrode 690b can be exposed. In various embodiments of the present disclosure, opposite surfaces of the first dam 680a (e.g., one surface contacting the adhesive film 130 and another surface contacting the second dam 680b) can be parallel, but embodiments of the present disclosure are not limited thereto. For example, slopes of the opposite surfaces of the first dam 680a can be different from each other, and need not be vertically aligned.

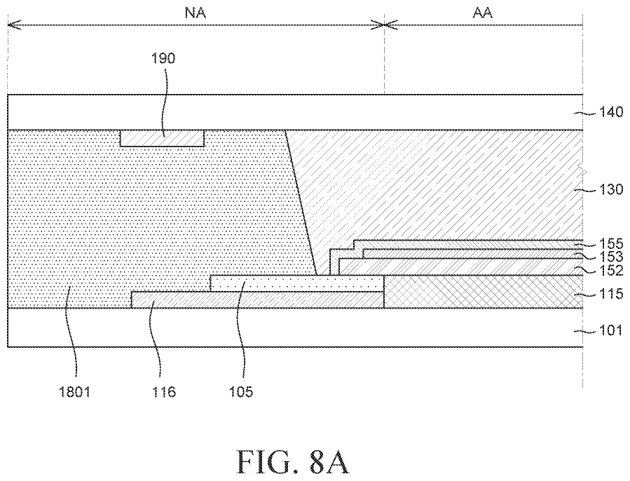

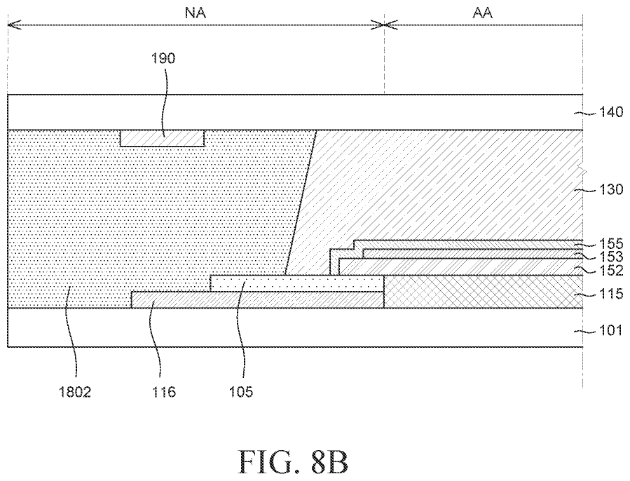

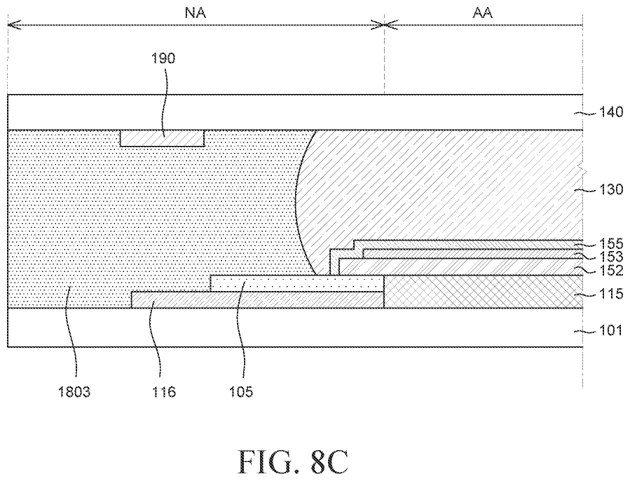

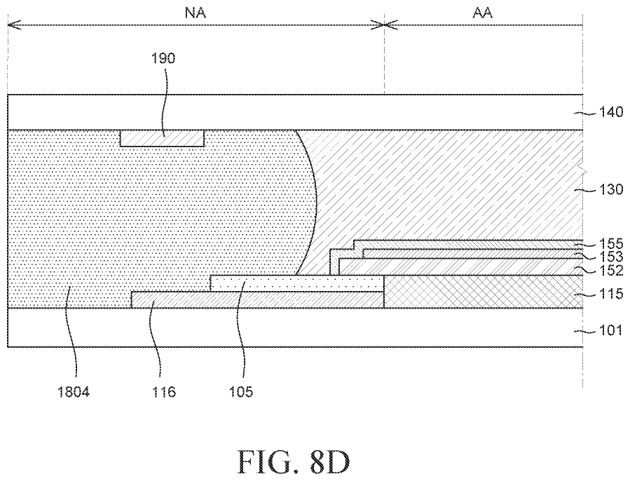

FIGS. 8A-8D are cross-sectional views of the display device taken along IV-IV′ of FIG. 2 according to other example embodiments of the present disclosure.

Since configurations of a display device of FIGS. 8A-8D according to other example embodiments of the present disclosure are substantially identical to those of the display device 100 in FIGS. 2 to 4 with only differences in configurations of dams 1801-1804, redundant descriptions will be omitted. The same reference numerals will be used for the same components. Hereinafter, a description of the same reference numerals can be made with reference to FIGS. 2 to 4.

Referring to FIGS. 8A-8D, the dams 1801 to 1804 each includes a first surface that contacts or is adjacent to the adhesive film 130, and a second surface that is exposed to an exterior of the display device 100. The second surface that is exposed to the exterior of the display device 100 can be flush or coplanar with an edge of the encapsulation substrate 140 and an edge of the substrate 101. Meanwhile the first surface that that contacts or is adjacent to the adhesive film 130 is opposite to the second surface that is exposed to the exterior of the display device 100. As shown in FIGS. 8A-8D, the first surface and the second surface can be not parallel to each other, which is different from the first and second surfaces shown in FIG. 4.

For example, as shown in FIGS. 8A and 8B, the first surface can be slanted in the cross-sectional view, while as shown in FIGS. 8C and 8D, the first surface can be concave or convex in relations to the adhesive film 130. Accordingly, each of the dams 1801-1804 can have a first surface that changes in a height or thickness direction in the cross-sectional view. Accordingly, in each of the dams 1801-1804, a slope of the second surface can be different from a slope of the first surface.

In addition to the different slopes between the first surface and the second surface of each of the dams 1801-1804, widths of the each of the dams 1801-1804 can vary between a top section (e.g., the part of the dams 1801-1804 that contact the encapsulation substrate 140) and a bottom section (e.g., the part of the dams 1801-1804 that contact the substrate 101). In embodiments of the present disclosure, a middle section that is between the top section and the bottom section can also have a width that is different from the width of one or both of the top section and the bottom section.

For example, with reference to FIG. 8A, the width of the top section of the dam 1801 can be less than the width of the bottom section of the dam 1801. Meanwhile, the width of the middle section of the dam 1801 can be greater than the width of the top section but less than the width of the bottom section. In the embodiment of the present disclosure shown in FIG. 8A, the slope of the first surface of the dam 1801 can be the same at the top section, the middle section and the bottom section, and there is an increase of the width of the dam 1801 in going from the top section towards the bottom section. But embodiments of the present disclosure are not limited thereto, and the change of the width can be different.

For example, with reference to FIG. 8B, the width of the top section of the dam 1802 can be greater than the width of the bottom section of the dam 1802. Meanwhile, the width of the middle section of the dam 1802 can be less than the width of the top section, and greater than the width of the bottom section. In the embodiment of the present disclosure shown in FIG. 8B, the slope of the first surface of the dam 1802 can be the same at the top section, the middle section and the bottom section, and there is a decrease of the width of the dam 1802 in going from the top section towards the bottom section. But embodiments of the present disclosure are not limited thereto, and the change of the width can be different.

For example, with reference to FIG. 8C, the width of the top section of the dam 1803 can be approximately the same as the width of the bottom section of the dam 1803. Meanwhile, the width of the middle section of the dam 1803 can be less than the width of the top section and the bottom section. In the embodiment of the present disclosure shown in FIG. 8C, the slope of the first surface of the dam 1803 can vary at the top section, the middle section and the bottom section, and there is a change of the width of the dam 1803 in going from the top section towards the bottom section. A cross sectional shape of the first surface of the dam 1803 in FIG. 8C is a concave shape. But embodiments of the present disclosure are not limited thereto, and the change of the width can be different.

For example, with reference to FIG. 8D, the width of the top section of the dam 1804 can be approximately the same as the width of the bottom section of the dam 1804. Meanwhile, the width of the middle section of the dam 1804 can be greater than the width of the top section and the bottom section. In the embodiment of the present disclosure shown in FIG. 8D, the slope of the first surface of the dam 1804 can vary at the top section, the middle section and the bottom section, and there is a change of the width of the dam 1804 in going from the top section towards the bottom section. A cross sectional shape of the first surface of the dam 1804 in FIG. 8D is a convex shape. But embodiments of the present disclosure are not limited thereto, and the change of the width can be different.

For example, the cross section shape of the first surface of the dam can include at least one of a straight slope, a convex shape, a concave shape and a vertical surface. One or more of such shapes can be provided for the first surface, whereby both the concave and convex shapes can be provided in different locations, such as a top half and a bottom half, respectively of the dam.

In various embodiments of the present disclosure, the cross sectional shape of the first surface of the dam can be different from the cross sectional shape of the second surface. For example, in the dams 1801-1804, the second surface can be vertical, and the first surface can be non-vertical, but embodiments of the present disclosure are not limited thereto.

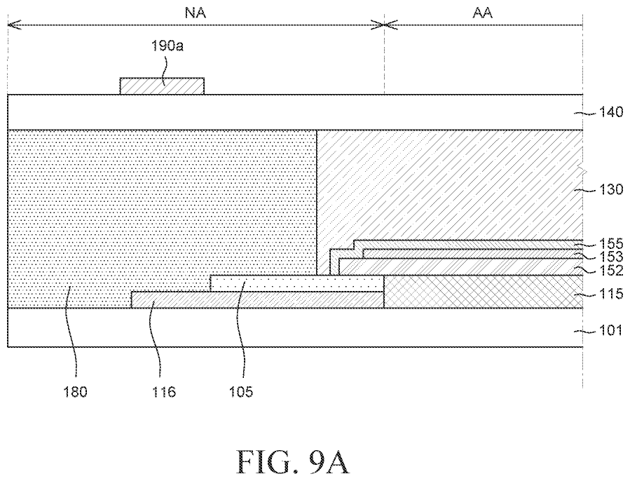

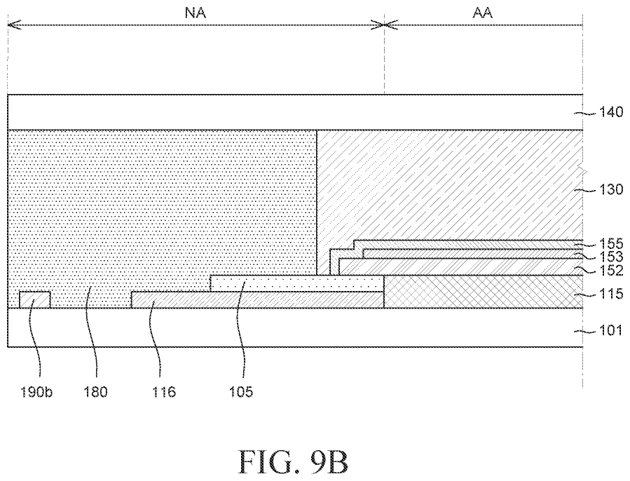

FIGS. 9A and 9B are cross-sectional views of the display device taken along IV-IV′ of FIG. 2 according to other example embodiments of the present disclosure. Since configurations of a display device of FIGS. 9A and 9B according to other example embodiments of the present disclosure are substantially identical to those of the display device 100 in FIGS. 2 to 4 with only differences in configurations of electrodes 190a and 190b, redundant descriptions will be omitted. The same reference numerals will be used for the same components. Hereinafter, a description of the same reference numerals can be made with reference to FIGS. 2 to 4.

Referring to FIG. 9A, an electrode 190a can be disposed on the encapsulation substrate 140. Specifically, the electrode 190a can be disposed at an upper surface (or an outer surface) opposite from a lower surface (or an inner surface) of the encapsulation substrate 140 that contacts the dam 180. The electrode 190a can be disposed to overlap the dam 180. Also, the electrode 190a can be disposed to overlap at least one of the GIP unit 116 and the planarization layer 105, but embodiments of the present disclosure is not limited thereto. For example, the electrode 190a can be disposed further away from the active area AA so as not to overlap the GIP unit 116 or the planarization layer 105. When the electrode 190a is disposed at the upper surface of the encapsulation substrate 140, more surface area of the dam 180 can directly contact the lower surface of the encapsulation substrate 140.

When the electrode 190a is disposed at the upper surface of the encapsulation substrate 140 and is applied with a voltage, such as the positive (+) voltage, while the minus (−) voltage is applied to the electric field application nozzle 510, an electric field for depositing the dam forming material can be generated between the electrode 190a and the electric field application nozzle 510 through the encapsulation substrate 140, and the dam 180 can be formed on the lower surface of the encapsulation substrate 140 towards the substrate 101. The electrode 190a can include the same material as one of the anode 151 and the cathode 153, but can be also formed using different materials. The electrode 190a can include at least one metal or a metallic material, an alloy, or a transparent conductive material, such as a conductive oxide. But embodiments of the present disclosure are not limited thereto.

Referring to FIG. 9B, an electrode 190b can be disposed on the substrate 101. Specifically, the electrode 190b can be disposed at an upper surface (or an inner surface) opposite from a lower surface (or an outer surface) of the substrate 101. The upper surface of the substrate 101 can contact the dam 180. The electrode 190b can be disposed to overlap the dam 180. Also, the electrode 190b can be disposed to not overlap at least one of the GIP unit 116 and the planarization layer 105, but embodiments of the present disclosure is not limited thereto.

When the electrode 190b is disposed at the upper surface of the substrate 101, a material of at least one of the anode 151 and the cathode 153 can be used to form the electrode 190b. When the material of at least one of the anode 151 and the cathode 153 can be used to form the electrode 190b, the electrode 190b can be formed at the same time as at least one of the anode 151 and the cathode 153 is formed, but embodiments of the present disclosure are not limited thereto, and the electrode 190b can be formed at different time from that of at least one of the anode 151 and the cathode 153, and can be formed using different materials. The electrode 190b can include at least one metal or a metallic material, an alloy, or a transparent conductive material, such as a conductive oxide. But embodiments of the present disclosure are not limited thereto. The example embodiments of the present disclosure can also be described as follows:

According to an aspect of the present disclosure, there is provided a display device. The display device comprises a substrate including an active area and a non-active area surrounding the active area, an encapsulation substrate disposed over the substrate, an adhesive film disposed between the substrate and the encapsulation substrate, a dam disposed in the non-active area between the substrate and the encapsulation substrate to surround the adhesive film and an electrode disposed on a lower surface of the encapsulation substrate overlapping the dam.

The display device can further include at least one flexible film disposed on one side of the substrate.

A width of the non-active area disposed on the one side of the substrate on which the flexible film is disposed can be different from a width of the non-active area disposed on all of other sides of the substrate.

A width of the non-active area disposed on the one side of the substrate can be greater than a width of the non-active area disposed on all of the other sides of the substrate.

A width of the dam disposed on the one side of the substrate can be greater than a width of the dam disposed on all of the other sides of the substrate.

A side surface of the dam disposed on all of the other sides of the substrate can be disposed on the same plane as a side surface of the substrate and a side surface of the encapsulation substrate.

The dam can include a first dam disposed to surround the active area and a second dam disposed to surround the first dam.

The first dam can include a material having adhesion higher than that of a material constituting the second dam, and the second dam can include a material having moisture permeability higher than a material constituting the first dam.

The electrode can include a first electrode disposed to overlap the first dam and a second electrode disposed to overlap the second dam.

Voltages of different polarities can be applied to the first electrode and the second electrode when the first dam and the second dam are simultaneously formed.

When forming the first dam and when forming the second dam, voltages of different polarities can be applied to the first electrode and the second electrode, respectively.

A side surface of the second dam can be disposed on the same plane as a side surface of the substrate and a side surface of the encapsulation substrate.

At least one of the first electrode and the second electrode can be exposed on one side of the substrate.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a substrate including an active area and a non-active area adjacent to the active area;
an encapsulation substrate disposed over the substrate;
a dam disposed in the non-active area between the substrate and the encapsulation substrate; and
an electrode disposed on a first surface of the encapsulation substrate or the substrate, and overlapping the dam.

2. The display device of claim 1, wherein the first surface of the encapsulation substrate or the substrate is a surface that faces towards the dam.

3. The display device of claim 1, wherein the first surface of the encapsulation substrate is a surface that faces away from the dam.

4. The display device of claim 1, further comprising:
at least one flexible film disposed on one side of the substrate.

5. The display device of claim 4, wherein a width of the non-active area disposed on the one side of the substrate on which the flexible film is disposed is different from a width of the non-active area disposed on all of other sides of the substrate.

6. The display device of claim 5, wherein the width of the non-active area disposed on the one side of the substrate is greater than the width of the non-active area disposed on all of the other sides of the substrate.

7. The display device of claim 5, wherein a width of the dam disposed on the one side of the substrate is greater than a width of the dam disposed on all of the other sides of the substrate.

8. The display device of claim 5, wherein a side surface of the dam disposed on all of the other sides of the substrate is disposed on a same plane as a side surface of the substrate and a side surface of the encapsulation substrate.

9. The display device of claim 1, wherein the dam includes:
a first dam disposed to surround the active area; and
a second dam disposed to surround the first dam.

10. The display device of claim 9, wherein the first dam includes a material having adhesion higher than that of a material constituting the second dam, and
wherein the material constituting the second dam has a moisture permeability higher than the material included in the first dam.

11. The display device of claim 9, wherein the electrode includes:
a first electrode disposed to overlap the first dam; and
a second electrode disposed to overlap the second dam.

12. The display device of claim 9, wherein a side surface of the second dam is disposed on a same plane as a side surface of the substrate and a side surface of the encapsulation substrate.

13. The display device of claim 11, wherein at least one of the first electrode and the second electrode is exposed on one side of the substrate.

14. The display device of claim 1, wherein the electrode loops around a periphery of the active area.

15. A display device, comprising:
a substrate including an active area and a non-active area adjacent the active area;
an encapsulation substrate disposed over the substrate;
an adhesive film disposed between the substrate and the encapsulation substrate; and
a dam disposed in the non-active area at a periphery of the active area,
wherein the dam includes a first surface facing towards the adhesive film, and a second surface facing away from the adhesive film, and
wherein the first surface and the second surface are not parallel to each other.

16. The display device of claim 15, wherein the second surface of the dam is coplanar with an edge of the encapsulation substrate and an edge of the substrate.

17. The display device of claim 15, wherein a first slope of the first surface of the dam and a second slope of the second surface of the dam are different in a cross sectional view.

18. The display device of claim 17, wherein the first slope of the first surface has a non-vertical slope and the second slope of the second surface has a vertical slope in the cross sectional view.

19. The display device of claim 17, wherein the first slope of the first surface is constant in the cross sectional view.

20. The display device of claim 17, wherein the first slope of the first surface is varying in the cross sectional view.

21. The display device of claim 20, wherein the first surface is one of concave or convex in the cross sectional view.

22. The display device of claim 15, wherein a width of the dam in a cross sectional view varies in a thickness direction of the dam.

23. The display device of claim 15, further comprising an electrode disposed on the encapsulation substrate or the substrate.
